(19) United States
(12) Patent Application Publication
(10) Pub. No.: US 2025/0022844 A1
(43) Pub. Date: Jan. 16, 2025

(54) SEMICONDUCTOR PACKAGE AND METHOD FOR MANUFACTURING THE SAME

(71) Applicant: Samsung Electronics Co., Ltd., Suwon-si (KR)

(72) Inventors: CHOONGBIN YIM, Suwon-si (KR); JONGKOOK KIM, Suwon-si (KR)

(21) Appl. No.: 18/444,359

(22) Filed: Feb. 16, 2024

(30) Foreign Application Priority Data
Jul. 13, 2023 (KR) 10-2023-0091016

(51) Int. Cl. H01L 25/065; H01L 23/00; H01L 23/31; H01L 23/498; H01L 23/522; H01L 23/528; H01L 25/00; H01L 25/18

(52) U.S. Cl. CPC H01L 25/0652; H01L 23/3128; H01L 23/49822; H01L 23/5223; H01L 23/5226; H01L 23/5286; H01L 24/08; H01L 24/16; H01L 24/32; H01L 24/73; H01L 25/18; H01L 25/50; H01L 2224/08146; H01L 2224/16225; H01L 2224/32145; H01L 2224/73253; H01L 2924/1437; H01L 2924/181

(57) ABSTRACT

A semiconductor package according to an embodiment may include, a redistribution layer structure; a first semiconductor stack structure on an upper surface of the redistribution layer structure, wherein the first semiconductor stack structure includes a first chiplet and a second chiplet disposed on the first chiplet; a second semiconductor stack structure on an upper surface of the redistribution layer structure side by side with the first semiconductor stack structure; a bridge die forming an electrical connection between the first semiconductor stack structure and the second semiconductor stack structure, the bridge die being disposed above the first semiconductor stack structure and the second semiconductor stack structure; and a surface mount device (SMD) disposed on an upper surface of at least one of the first semiconductor stack structure and the second semiconductor stack structure.

### CROSS-REFERENCE TO RELATED APPLICATION

This application claims priority to and the benefit of Korean Patent Application No. 10-2023-0091016 filed in the Korean Intellectual Property Office on Jul. 13, 2023, the entire contents of which is incorporated herein by reference.

### BACKGROUND OF THE INVENTION

### (a) Field of the Invention

The present disclosure relates to a semiconductor package and a method for manufacturing the same.

### (b) Description of the Related Art

The semiconductor industry seeks to increase integration density so that more passive or active devices can be integrated within a given area. The development of technology for miniaturizing a circuit line width of a front-end semiconductor process has gradually faced limitations resulting in slowing innovation related to the circuit line width. The semiconductor industry has supplemented the limitations of the front-end semiconductor processes by developing semiconductor package techniques capable of having high integration densities without corresponding advancements in miniaturizing circuit line widths. According to this trend, 3.5D packaging technology has been developed in which a bottom surface of high-bandwidth memory (HBM) and a bottom surface of chiplet stack structure are connected with a bridge die, a substrate is disposed under the bridge die, and a surface mount device (SMD) is disposed on the bottom surface of the substrate.

3.5 D package technology has resulted in increased integration density, but semiconductor industry seeks further integration density. Therefore, it is important to develop a new semiconductor packaging technology to address the problems of the conventional semiconductor packaging technology.

### SUMMARY OF THE INVENTION

In 3.5D package technology having the bridge die and the substrate disposed between the high-bandwidth memory (HBM) and the chiplet stack structure in the upper portion, and the surface mount device (SMD) in the lower portion, there exists a lengthy electrical path between the high-bandwidth memory (HBM) and the chiplet stack structure in the upper portion, and the surface mount device (SMD) in the lower portion. The lengthy electrical path makes it becomes difficult to realize a high-performance semiconductor package when the vertical thickness of the 3.5D package is thickened. In addition, since the surface mount device (SMD) is disposed under the substrate, the number of connection members disposed under the substrate is decreased, thereby increasing the horizontal size of the 3.5D package.

The present disclosure provides a semiconductor package and a method for manufacturing a semiconductor package, in which, in a 3.5D package, an upper surface of high-bandwidth memory (HBM) and an upper surface of chiplet stack structure are connected with a bridge die, a surface mount device (SMD) is disposed on at least one of the upper surface of high-bandwidth memory (HBM) and the upper surface of chiplet stack structure, and a redistribution layer structure is disposed on a bottom surface of high-bandwidth memory (HBM) and a bottom surface of chiplet stack structure.

A semiconductor package may include a redistribution layer structure, a first semiconductor stack structure on an upper surface of the redistribution layer structure, where the first semiconductor stack structure may include a first chiplet and a second chiplet on the first chiplet, a second semiconductor stack structure on the redistribution layer structure and side by side with the first semiconductor stack structure, a bridge die forming an electrical connection between the first semiconductor stack structure and the second semiconductor stack structure, the bridge die being disposed above the first semiconductor stack structure and the second semiconductor stack structure, and a surface mount device (SMD) on an upper surface of at least one of the first semiconductor stack structure and the second semiconductor stack structure.

A semiconductor package may include a redistribution layer structure, a first semiconductor stack structure on the redistribution layer structure, where the first semiconductor stack structure may include, a first chiplet, a first molding material molding a side surface of the first chiplet, a second chiplet on the first chiplet and on the first molding material such that the first chiplet is disposed between the redistribution layer structure and the second chiplet, and a first interconnection layer between the first chiplet and the second chiplet, a second semiconductor stack structure disposed on the redistribution layer structure and side by side with the first semiconductor stack structure, a bridge die configured to electrically connect the first semiconductor stack structure and the second semiconductor stack structure, on the first semiconductor stack structure, the bridge die being disposed above the second semiconductor stack structure, a surface mount device (SMD) disposed above at least one of the first semiconductor stack structure and the second semiconductor stack structure, and a second molding material covering the first semiconductor stack structure, the second semiconductor stack structure, the bridge die, and the surface mount device, on the redistribution layer structure.

A method for manufacturing a semiconductor package may include mounting a first semiconductor stack structure on a redistribution layer structure, where the first semiconductor stack structure may include a first chiplet and a second chiplet on the first chiplet, mounting a second semiconductor stack structure, on the redistribution layer structure and side by side with the first semiconductor stack structure, mounting a bridge die on the first semiconductor stack structure and on the second semiconductor stack structure, where the bridge die is positioned above the first semiconductor stack and the second semiconductor stack structure and electrically connects the first semiconductor stack structure and the second semiconductor stack structure, and mounting a surface mount device (SMD) on at least one of the first semiconductor stack structure and the second semiconductor stack structure.

The surface mount device (SMD), which was conventionally disposed under the substrate, may be disposed on the upper surface of the high-bandwidth memory (HBM) and the upper surface of the chiplet stack structure. Accordingly, the length of an electrical path between the high-bandwidth memory (HBM), the chiplet stack structure, and the surface mount device (SMD) may be reduced.

The bridge die, which is conventionally disposed between the upper surface of the substrate, and the bottom surface of the high-bandwidth memory (HBM) and the chiplet stack structure, and buried in the silicon interposer, may be disposed on the upper surface of the high-bandwidth memory (HBM) and the upper surface of the chiplet stack structure. Accordingly, the silicon interposer may not be used, and lengths of electrical paths between the high-bandwidth memory (HBM) and the external connection member of the semiconductor package and between the chiplet stack structure and the external connection member of the semiconductor package may be reduced.

By using the redistribution layer structure without using a conventional substrate, the redistribution layer structure may be connected to fine pitch I/Os of the chiplet stack structure and the high-bandwidth memory (HBM).

In addition, the surface mount device (SMD), which conventionally was disposed alongside the external connection members under the substrate, may be disposed on the upper surface of the high-bandwidth memory (HBM) and on the upper surface of the chiplet stack structure. Accordingly, the number of the external connection members that had to be reduced to secure an area where the surface mount device (SMD) is disposed may not be reduced, and the size of the 3.5D package may be reduced.

### BRIEF DESCRIPTION OF THE DRAWINGS

FIG. 1 is a cross-sectional view showing a semiconductor package of an embodiment.

FIG. 2 is a top plan view showing an upper surface of an embodiment of a semiconductor package.

FIG. 3 is a top plan view showing another upper surface of another embodiment of a semiconductor package.

FIG. 4 is a cross-sectional view showing a semiconductor package of another embodiment.

FIG. 5 to FIG. 10 are cross-sectional views showing a method for manufacturing a first semiconductor stack structure of an embodiment.

FIG. 11 to FIG. 17 are cross-sectional views showing a method for manufacturing a semiconductor package of an embodiment.

### DETAILED DESCRIPTION OF THE EMBODIMENTS

Hereinafter, embodiments of the inventive concept will be hereinafter described in detail with reference to the accompanying drawings. The inventive concept may be implemented in various forms and is not limited to the embodiments described herein.

The drawings and description are to be regarded as illustrative in nature and not restrictive. Like reference numerals designate like elements throughout the specification. The same reference numeral may be used to designate a plurality of like elements and unless otherwise indicated, a reference numeral does not identify any individual element of the plurality of like elements. As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”. Ordinal numbers such as “first,” “second,” “third,” etc. may be used simply as labels of certain elements, steps, etc. to distinguish such elements, steps, etc., from one another and unless otherwise indicated, do not represent an order. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Further, in the drawings, the size and thickness of each element are arbitrarily illustrated for ease of description, and the inventive concept is not necessarily limited to the size and/or thickness of the embodiments illustrated in the drawings.

Throughout this specification and the claims that follow, when an element is referred to as being “coupled or connected” to another element, the elements may be “directly coupled or connected” in which there are no intervening elements present at a point of contact between the elements or “indirectly coupled or connected” in which other elements may serve to couple or connect the elements such that there is no point of contact between the elements. When no indication is given as to whether elements are directly or indirectly coupled or connected, either directly or indirectly coupled or connected is possible. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element (e.g., contacting the other element) or intervening elements may also be present. In contrast, when an element is referred to as being “directly on” another element, there are no intervening elements present at a point of contact between the elements. Further, in the specification, the word “above” is broadly construed as a higher vertical position relative to a base of a structure and does not necessarily mean positioned on the upper side of the object portion based on a gravitational direction. Additionally, an element may be described as “directly above” another element when they overlap horizontally.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a method for manufacturing the semiconductor package 100, will be described with reference to drawings.

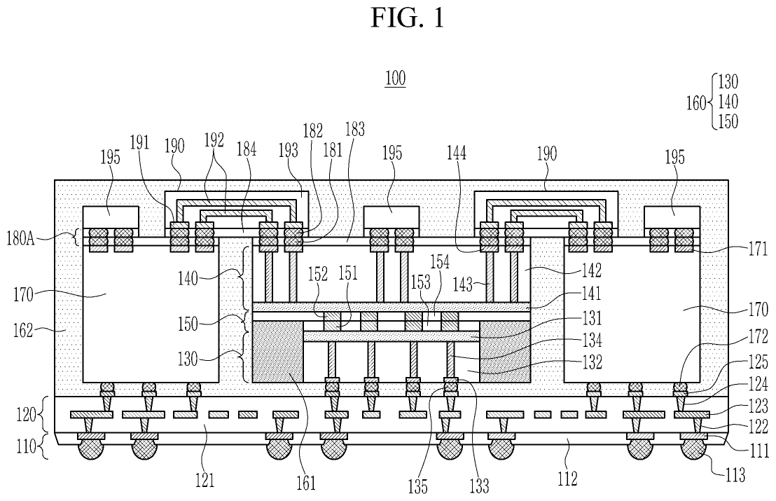

FIG. 1 is a cross-sectional view showing the semiconductor package 100 of an embodiment.

Referring to FIG. 1, bridge dies 190 and surface mount devices (SMD) 195 may be disposed on an upper surface of a first semiconductor stack structure 160 and an upper surface of a second semiconductor stack structure 170. The bridge dies 190 and the surface mount devices may be electrically connected to the first semiconductor stack structure 160 and/or the second semiconductor stack structure 170 through hybrid bonding.

The semiconductor package 100 may include an external connection structure 110, a redistribution layer structure 120, the first semiconductor stack structure 160, second semiconductor stack structures 170, bridge dies 190, the surface mount devices (SMD) 195, and a molding material 162. The molding material 162 may be referred to as a second molding material 162 since the molding material may surround the second semiconductor stack structures 170. In an embodiment, the semiconductor package 100 may include a 3.5D semiconductor package. In an embodiment, the semiconductor package 100 may include a fan out wafer level package (FOWLP) or a fan out panel level package (FOPLP).

The external connection structure 110 may be disposed on a bottom surface of the redistribution layer structure 120. The external connection structure 110 may include conductive pads 111, an insulation layer 112, and external connection members 113. The conductive pads 111 may electrically connect first redistribution vias 122 of the redistribution layer structure 120 to corresponding external connection members 113. The insulation layer 112 may include a plurality of openings for soldering. The insulation layer 112 may prevent the external connection members 113 from being short-circuited with other external connection members 113 (e.g., electrically insulate the external connection members from one another). The external connection members 113 may electrically connect the semiconductor package 100 to an external device.

The redistribution layer structure 120 may include a dielectric layer 121 which may include first redistribution vias 122, first redistribution lines 123, and second redistribution vias 124 within the dielectric layer 121. In another embodiment, a redistribution layer structure 120 may include a differing number of redistribution lines and redistribution vias than what is shown in FIG. 1 but is included within the scope of the inventive concept.

Each of the first redistribution vias 122 may be disposed between a corresponding first redistribution line 123 and a corresponding conductive pad 111. The first redistribution vias 122 may electrically connect, in a vertical direction, the first redistribution lines 123 to external connection members 113 connected to the conductive pads 111. The first redistribution lines 123 may be disposed between the first redistribution vias 122 and a second redistribution vias 124. The first redistribution lines 123 may electrically connect the first redistribution vias 122 and the second redistribution vias 124, in a horizontal direction. Each of the second redistribution vias 124 may be disposed between a corresponding bonding pad 125 and a corresponding first redistribution line 123. The second redistribution vias 124 may electrically connect, in the vertical direction, the bonding pads 125 to the first redistribution lines 123.

A first bonding pad 125 may be disposed between the second redistribution via 124 and a connection member 135 of the first semiconductor stack structure 160, and a second bonding pad 125 may be disposed between the second redistribution via 124 and a connection member 172 of the second semiconductor stack structure 170. The first bonding pad 125 may electrically connect, in the vertical direction, the connection member 135 of the first semiconductor stack structure 160 to the second redistribution via 124, and the second bonding pad may electrically connect a connection member 172 of the second semiconductor stack structure 170 to the second redistribution via 124.

According to the present disclosure, by using the redistribution layer structure 120 instead of the conventionally used substrate, the redistribution layer structure 120 may be connected to the fine pitch I/Os of the first semiconductor stack structure 160 (for example, chiplet stack structure) and the second semiconductor stack structure 170 (for example, high-bandwidth memory (HBM)).

The first semiconductor stack structure 160 may be disposed on the redistribution layer structure 120. The first semiconductor stack structure 160 may be a chiplet stack structure formed by stacking chiplets. The first semiconductor stack structure 160 may include a first chiplet 130, a second chiplet 140 on the first chiplet 130, a first interconnection structure 150 between the first chiplet 130 and the second chiplet 140, and a molding material 161 referred to hereafter as a first molding material 161. A chiplet is a functional semiconductor block manufactured by distinguishing components of a high-performance processor according to functions. Chiplets that do not require the use of the latest process may be manufactured by applying an inexpensive old process, and chiplets that require the use of the latest process may be manufactured by applying the latest process. As such, the chiplets may be separately manufactured according to functions, and a single high-performance processor may be manufactured by connecting the manufactured chiplets. Each chiplet cannot operate as a unit chip, and a high-performance processor manufactured by connecting these chiplets may overcome the performance limitations of conventional single-chip processors.

The first chiplet 130 may include a first active region 131, a first chiplet base 132, lower connection pads 133, first through-silicon vias (TSVs) 134, and connection members 135. In an embodiment, the first chiplet 130 may include a central processing unit (CPU) and/or a graphic processing unit (GPU). The first chiplet 130 may be electrically connected to the second chiplet 140 at an upper portion of the first chiplet 130 by the first interconnection structure 150. The lower connection pad 133 may be electrically connected to a bonding pad 125 through a connection member 135. The redistribution layer structure 120 may be disposed below the first chiplet 130. Side surfaces of the first chiplet 130 may be surrounded by the first molding material 161.

The first active region 131 may be positioned on a front side of the first chiplet 130 which may be an upper side of the first chiplet. The first active region 131 may be positioned in an uppermost level in the first chiplet 130. The first active region 131 may be positioned on a surface facing the second chiplet 140. The first active region 131 may be disposed between the first through-silicon vias 134 and lower bonding pads 151 of the first interconnection structure 150. The first active region 131 may be directly electrically connected to a lower bonding pad 151 of the first interconnection structure 150. In an embodiment, the first active region 131 may include logic circuit.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

The first chiplet base 132 may be positioned in a back side of the first chiplet 130 facing away from the first active region 131. The lower connection pad 133 and the first through-silicon vias 134 may be disposed in the first chiplet base 132. The first chiplet base 132 may include a silicon material. The lower connection pad 133 may be disposed between the first through-silicon via 134 and the connection member 135. The lower connection pad 133 may electrically connect the first through-silicon via 134 to the connection member 135.

The first through-silicon via 134 may be disposed between the first active region 131 and the lower connection pad 133. The first through-silicon via 134 may electrically connect the first active region 131 to the lower connection pad 133. One end of the first through-silicon via 134 may contact the first active region 131, and the other end of the first through-silicon via 134 may contact the lower connection pad 133. The first through-silicon via 134 may extend downward (e.g., toward the redistribution layer 120) in a direction from the first active region 131 of the first chiplet 130 to a back side of the first chiplet 130. Since the first through-silicon vias 134 is disposed within the first chiplet 130 and the first chiplet 130 and the second chiplet 140 can be arranged with their active regions facing one another and interconnected through the first interconnection structure 150, the speed at which signals and power are transferred and responded between the first chiplet 130 and the second chiplet 140 may be increased due to the relatively short electrical path through the first interconnection structure 150.

The connection member 135 may be disposed between the lower connection pad 133 and the second redistribution via 124 of the redistribution layer structure 120. The connection member 135 may electrically connect the lower connection pad 133 to the second redistribution via 124 of the redistribution layer structure 120. In an embodiment, the connection members 135 may be micro-bumps or solder balls.

In an embodiment, the lower connection pad 133 may be formed of and/or include at least one of copper, aluminum, silver, tin, gold, nickel, lead, titanium, and an alloy thereof. In an embodiment, the first through-silicon via 134 may be formed of and/or include at least one of tungsten, aluminum, copper, and an alloy thereof. In an embodiment, the connection member 135 may be formed of and/or include at least one of tin, silver, lead, nickel, copper, or an alloy thereof.

The second chiplet 140 may include a second active region 141, a second chiplet base 142, second through-silicon vias 143, and an upper connection pad 144. In an embodiment, the second chiplet 140 may include a static random access memory (SRAM). The second chiplet 140 may be electrically connected to the first chiplet 130 in the lower portion by the first interconnection structure 150. A second interconnection structure 180A may be disposed in an upper portion of the second chiplet 140. The second chiplet 140 may be electrically connected to at least one of the bridge die 190 and the surface mount device (SMD) 195 by the second interconnection structure 180A. The side surfaces of the second chiplet 140 may be surrounded by the second molding material 162. The footprint of the first chiplet 130 may be included in the footprint of the second chiplet 140 (e.g., the first chiplet 130 may be directly below the second chiplet 140 and not extend laterally beyond a projected side of the second chiplet 140).

The second active region 141 may be positioned on a front side of the second chiplet 140. The second active region 141 may be positioned in a lowermost level in the second chiplet 140. The second active region 141 may be disposed between the second through-silicon vias 143 and upper bonding pads 152 of the first interconnection structure 150. The second active region 141 may electrically connect a second through-silicon via 143 to an upper bonding pad 152 of the first interconnection structure 150. In an embodiment, the second active region 141 may include logic circuit.

The second chiplet base 142 may be positioned at a back side of the second chiplet 140 opposite from the second active region 141. The upper connection pad 144 and the second through-silicon vias 143 may be disposed in the second chiplet base 142. The second chiplet base 142 may be formed of and/or include a silicon material. The upper connection pad 144 may be disposed between the second through-silicon via 143 and a lower bonding pad 181 of the second interconnection structure 180A. The upper connection pad 144 may electrically connect the lower bonding pad 181 of the second interconnection structure 180A to the second through-silicon via 143.

The second through-silicon via 143 may be disposed between the second active region 141 and the upper connection pad 144. The second through-silicon via 143 may extend in an upward direction from the second active region 141 to a back side of the second chiplet 140. The second through-silicon via 143 may electrically connect the upper connection pad 144 to the second active region 141. One end of the second through-silicon via 143 may contact the second active region 141, and the other end of the second through-silicon via 143 may contact the upper connection pad 144. As such, since the second through-silicon vias 143 is disposed within the second chiplet 140, connected to the first chiplet 130 through the first interconnection structure 150, and connected to a bridge die 190 or the surface mount device (SMD) through the second interconnection structure 180A, the speed at which signals and power are transferred and responded, between the first chiplet 130 and the second chiplet 140 and between the second chiplet 140 and the second semiconductor stack structure 170, may be increased due to the relatively short electrical path.

In an embodiment, the second through-silicon via 143 may be formed of and/or include at least one of tungsten, aluminum, copper, and an alloy thereof. In an embodiment, the upper connection pad 144 may be formed of and/or include at least one of copper, aluminum, silver, tin, gold, nickel, lead, titanium, and an alloy thereof.

The first interconnection structure 150 may be disposed between the first chiplet 130 and the second chiplet 140 and between the first molding material 161 and the second chiplet 140. The first interconnection structure 150 may include the lower bonding pads 151, the upper bonding pads 152, a lower silicon insulation layer 153 and an upper silicon insulation layer 154. The lower bonding pads 151 and the upper bonding pads 152 may electrically connect the second chiplet 140 to the first chiplet 130.

In the semiconductor package 100 according to the present disclosure, the first chiplet 130 and the second chiplet 140 may be bonded by hybrid bonding by using the first interconnection structure 150. Hybrid bonding bonds two devices by fusing the same materials of the two devices using the bonding properties of the same material. Here, hybrid means that two different types of bonding are made, for example, bonding two devices with a first type of metal-metal bonding and a second type of non-metal-non-metal bonding. Hybrid bonding makes it possible to form I/Os with a fine pitch.

The lower bonding pads 151 formed on the first chiplet 130 may be directly bonded to the upper bonding pads 152 formed under the second chiplet 140 by metal-metal hybrid bonding, and the lower silicon insulation layer 153 formed on the first chiplet 130 may be directly bonded to the upper silicon insulation layer 154 formed under the second chiplet 140 by non-metal-non-metal hybrid bonding.

The second semiconductor stack structures 170 may be disposed on the redistribution layer structure 120. The second semiconductor stack structures 170 may be a high-bandwidth memory (HBM). High-bandwidth memory (HBM) is a high-performance three-dimensional (3D) stacked dynamic random access memory (DRAM). A high-bandwidth memory (HBM) is manufactured by vertically stacking memory dies by performing hybrid bonding or using micro-bumps to form a single memory stack. High-bandwidth memory (HBM) that has multiple memory channels through a memory stack in which memory dies are vertically stacked, may simultaneously realize shorter latency and higher bandwidth than conventional DRAM products, and may reduce the total area occupied by individual DRAMs on a substrate, and therefore, it is advantageous in terms of high bandwidth compared to area and has the advantage of reducing power consumption.

The second semiconductor stack structures 170 may include a buffer die (not shown) and a plurality of memory dies (not shown) stacked on the buffer die. The second semiconductor stack structures 170 may include upper connection pads 171 and connection members 172. The upper connection pad 171 may be disposed under the lower bonding pad 181 of the second interconnection structure 180A. The connection member 172 may be disposed on the bonding pad 125 of the redistribution layer structure 120. In an embodiment, the upper connection pad 171 may be formed of and/or include at least one of copper, aluminum, silver, tin, gold, nickel, lead, titanium, and an alloy thereof. The connection member 172 may electrically connect the second semiconductor stack structure 170 to the bonding pad 125 of the redistribution layer structure 120. In an embodiment, the connection member 172 may include micro-bumps or solder balls.

The bridge die 190 may be disposed above the first semiconductor stack structure 160 and the second semiconductor stack structure 170. The bridge die 190 may be disposed on a portion of an upper surface of the first semiconductor stack structure 160, and on a portion of an upper surface of the second semiconductor stack structure 170. The bridge die 190 may be electrically connected to the first semiconductor stack structure 160 and the second semiconductor stack structure 170 by the second interconnection structure 180A. The first semiconductor stack structure 160 and the second semiconductor stack structure 170 may exchange signals and power through the bridge die 190.

The bridge die 190 may include lower connection pads 191, connection lines 192, and a bridge die base 193. In an embodiment, the bridge die 190 may include a silicon bridge. A lower connection pad 191 may be disposed between an upper bonding pad 182 and a connection line 192. The lower connection pad 191 may electrically connect the connection line 192 to the upper bonding pad 182. The connection line 192 may be disposed between the lower connection pads 191 and electrically connect corresponding lower connection pads 191 to each other. The corresponding lower connection pads 191 may be sets of lower connection pads 191 laterally spaced from one another. The lower connection pads 191 may be formed of and/or include at least one of copper, aluminum, silver, tin, gold, nickel, lead, titanium, and an alloy thereof. The connection line 192 may be formed of and/or include at least one of copper, aluminum, silver, tin, gold, nickel, lead, titanium, tungsten, and an alloy thereof.

According to the present disclosure, having the bridge die disposed on the upper surface of the first semiconductor stack structure 160 (for example, chiplet stack structure) and the upper surface of the second semiconductor stack structure 170 (for example, high-bandwidth memory (HBM)) does not require the use of a silicon interposer and the length of an electrical path between the first semiconductor stack structure 160 and the external connection member 113 of the semiconductor package 100 and between the external connection member 113 and the second semiconductor stack structure 170 of the semiconductor package 100 may be reduced relative to conventional semiconductor packages.

The surface mount device (SMD) 195 may be disposed on at least one of the first semiconductor stack structure 160 and the second semiconductor stack structures 170. The surface mount device (SMD) 195 may be electrically connected to the first semiconductor stack structure 160 or the second semiconductor stack structure 170 by the second interconnection structure 180A. The surface mount device (SMD) 195 may provide additional functionality or programming throughout the semiconductor package 100. The surface mount device (SMD) 195 may include at least one of a resistor, an inductor, a capacitor, and a jumper. The surface mount device (SMD) 195 may be electrically connected to the first semiconductor stack structure 160 or the second semiconductor stack structure 170 by the second interconnection structure 180A.

According to the present disclosure, a surface mount device (SMD), which conventionally may be disposed under a substrate, may be disposed on the upper surface of the first semiconductor stack structure 160 (for example, chiplet stack structure) or on the upper surface of the second semiconductor stack structure 170 (for example, high-bandwidth memory (HBM)). In addition, surface mount devices (SMD), which conventionally may be disposed side by side with external connection members under a substrate, may be disposed on the upper surface of the first semiconductor stack structure 160 (for example, chiplet stack structure) and the upper surface of the second semiconductor stack structure 170 (for example, high-bandwidth memory (HBM)). Locating the surface mount device (SMD) on the upper surface of the first semiconductor stack structure 160 or the second semiconductor stack structure 170 may increase the available space below for external connections relative to convention placement of surface mount devices (SMD) below the substrate in which the number of external connection members may be reduced to secure the area where the surface mount device (SMD) are disposed. Accordingly, the size of a 3.5D semiconductor package may be reduced relative to a conventional semiconductor package that includes surface mount devices (SMD) below.

The second interconnection structure 180A may be disposed between the first semiconductor stack structure 160 and the bridge die 190, between the first semiconductor stack structure 160 and the surface mount device (SMD) 195, between a second semiconductor stack structure 170 and the bridge die 190, and between the second semiconductor stack structure 170 and the surface mount device (SMD) 195. The second interconnection structure 180A may include lower bonding pads 181, upper bonding pads 182, a lower silicon insulation layer 183, and an upper silicon insulation layer 184. The lower bonding pads 181 and the upper bonding pads 182 may electrically connect the bridge die 190 or the surface mount device (SMD) 195 to the first semiconductor stack structure 160 or the second semiconductor stack structure 170.

In a semiconductor package 100 according to the present disclosure, the bridge die 190 or the surface mount device (SMD) 195 may be bonded by hybrid bonding on the first semiconductor stack structure 160 or the second semiconductor stack structure 170 by using the first interconnection structure 180A.

The lower bonding pads 181 formed on the second semiconductor stack structure 170 or the first semiconductor stack structure 160 may be directly bonded to the upper bonding pads 182 formed under the bridge die 190 or the surface mount device (SMD) 195 by metal-metal hybrid bonding, and the lower silicon insulation layer 183 formed on the first semiconductor stack structure 160 or the second semiconductor stack structure 170 may be directly bonded to the upper silicon insulation layer 184 formed under the bridge die 190 or the surface mount device (SMD) 195 by non-metal-non-metal hybrid bonding.

The second molding material 162 may be disposed on the redistribution layer structure 120, and may surround the first semiconductor stack structure 160, the second semiconductor stack structures 170, the bridge dies 190, and the surface mount device (SMD) 195.

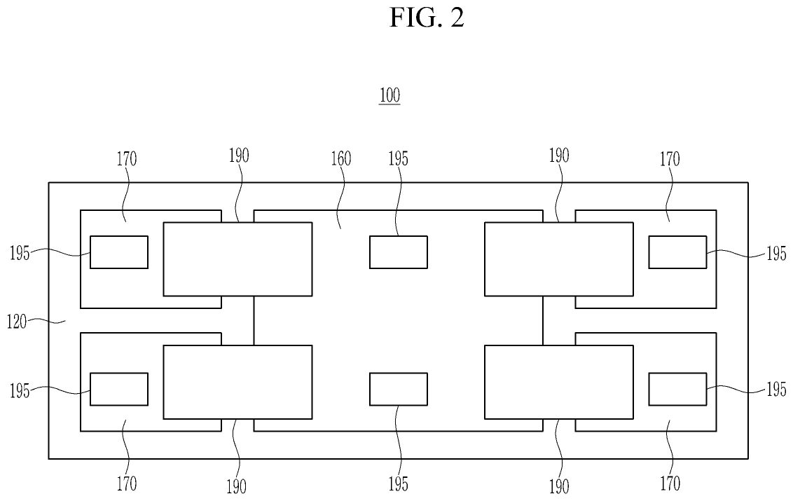

FIG. 2 is a top plan view showing an upper surface of the semiconductor package 100 of an embodiment.

Referring to FIG. 2, when the semiconductor package 100 excluding the second molding material 162 is viewed in a plan view, the first semiconductor stack structure 160 may be disposed at a central portion, and the second semiconductor stack structures 170 may be disposed around the first semiconductor stack structure 160. Each bridge die of the bridge dies 190 may electrically connect the first semiconductor stack structure 160 to each second semiconductor stack structure of the second semiconductor stack structures 170. The surface mount device (SMD) 195 may be disposed on the first semiconductor stack structure 160 and on each second semiconductor stack structure 170 among the second semiconductor stack structures 170.

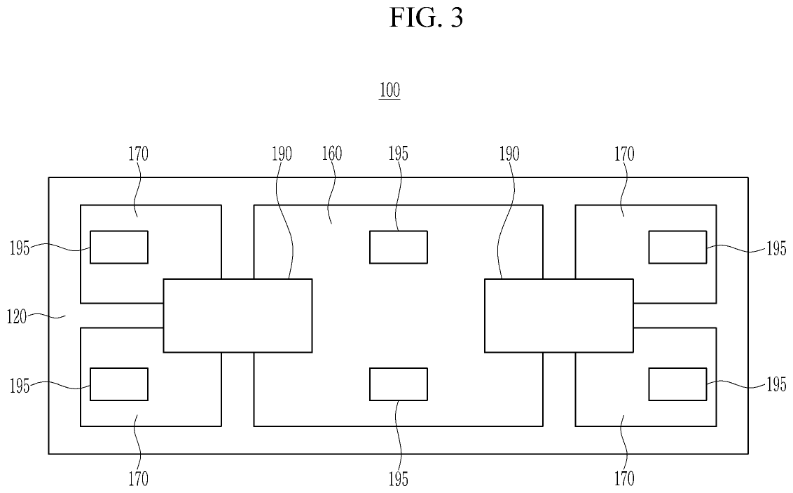

FIG. 3 is a top plan view showing the upper surface of the semiconductor package 100 of an embodiment.

Referring to FIG. 3, when the semiconductor package 100 excluding the second molding material 162 is viewed in a plan view, the first semiconductor stack structure 160 may be disposed at a central portion, and the second semiconductor stack structures 170 may be disposed around the first semiconductor stack structure 160. Each bridge die of the bridge dies 190 may electrically connect the first semiconductor stack structure 160 to a plurality of second semiconductor stack structures among the second semiconductor stack structures 170. The surface mount device (SMD) 195 may be disposed on the first semiconductor stack structure 160 and on each second semiconductor stack structure 170 among the second semiconductor stack structures 170.

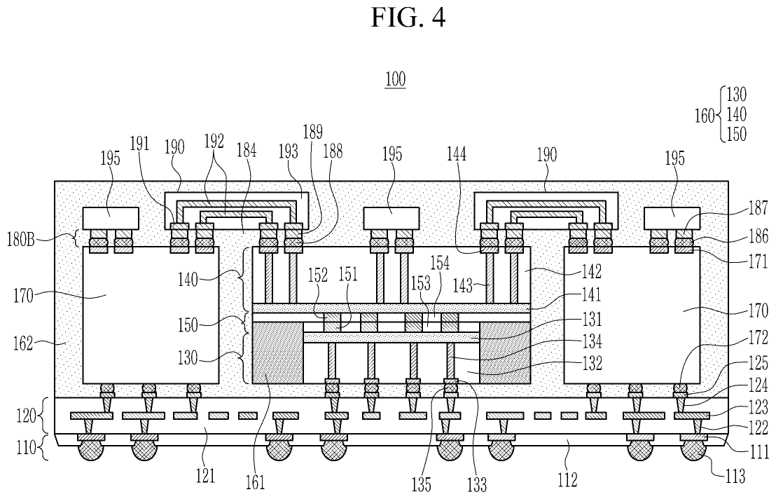

FIG. 4 is a cross-sectional view showing the semiconductor package 100 of another embodiment.

In FIG. 1, the first semiconductor stack structure 160 and the bridge die 190, the first semiconductor stack structure 160 and the surface mount device (SMD) 195, the second semiconductor stack structure 170 and the bridge die 190, and the second semiconductor stack structure 170 and the surface mount device (SMD) 195 are connected by hybrid bonding, but in comparison, in FIG. 4, the first semiconductor stack structure 160 and the bridge die 190, the first semiconductor stack structure 160 and the surface mount device (SMD) 195, the second semiconductor stack structure 170 and the bridge die 190, and the second semiconductor stack structure 170 and the surface mount device (SMD) 195 may be connected by flip chip bonding.

Referring to FIG. 4, a second interconnection structure 180B may be disposed between the first semiconductor stack structure 160 and the bridge die 190, between the first semiconductor stack structure 160 and the surface mount device (SMD) 195, between the second semiconductor stack structure 170 and the bridge die 190, and between the second semiconductor stack structure 170 and the surface mount device (SMD) 195.

Connection members 188 and bonding pads 189 may be disposed on a bottom surface of the bridge die 190 as the second interconnection structure 180B. A connection member 188 may be disposed between a bonding pad 189 and the upper connection pad 144 of the second chiplet 140 and between a bonding pad 187 and the upper connection pad 171 of the second semiconductor stack structure 170. The connection member 188 may electrically connect the bonding pad 189 on the upper connection pad 144 of the second chiplet 140 and the bonding pad 189 on the upper connection pad 171 of the second semiconductor stack structure 170. The bonding pad 189 may be disposed between the connection member 188 and the lower connection pad 191 of the bridge die 190. The bonding pad 189 may electrically connect the lower connection pad 191 of the bridge die 190 to the connection member 188.

In an embodiment, the connection member 188 may include micro-bumps or solder balls. In an embodiment, the connection member 188 may be formed of and/or include at least one of tin, silver, lead, nickel, copper, or an alloy thereof. In an embodiment, the bonding pad 189 may be formed of and/or include at least one of copper, aluminum, silver, tin, gold, nickel, lead, titanium, and an alloy thereof.

Connection members 186 and bonding pads 187 of the second interconnection structure 180B may be disposed on a bottom surface of the surface mount device (SMD) 195 as the second interconnection structure 180B. A connection member 186 may be disposed between the bonding pad 187 and the upper connection pad 144 of the second chiplet 140, or between the bonding pad 187 and the upper connection pad 171 of the second semiconductor stack structure 170. The connection member 186 electrically connect the bonding pad 187 on the upper connection pad 144 of the second chiplet 140, or the bonding pad 187 on the upper connection pad 171 of the second semiconductor stack structure 170. The bonding pad 187 may be disposed on the connection member 186. The bonding pad 187 may be electrically connected to the connection member 186.

In an embodiment, the connection member 186 may include micro-bumps or solder balls. In an embodiment, the connection member 186 may be formed of and/or include at least one of tin, silver, lead, nickel, copper, or an alloy thereof. In an embodiment, the bonding pad 187 may be formed of and/or include at least one of copper, aluminum, silver, tin, gold, nickel, lead, titanium, and an alloy thereof.

In FIG. 4, configurations other than the connection members 186 and bonding pads 187 of the second interconnection structure 180B are the same as those described in FIG. 1. Accordingly, the contents described in FIG. 1 may be equally applied to components other than the connection members 186 and bonding pads 187 of the second interconnection structure 180B in FIG. 4.

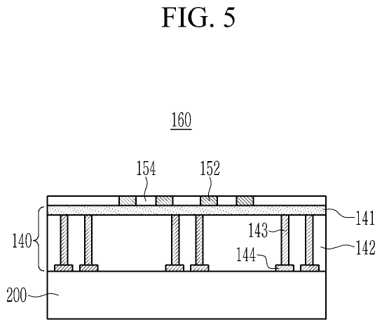

FIG. 5 to FIG. 10 are cross-sectional views showing a method for manufacturing the first semiconductor stack structure 160 of an embodiment.

FIG. 5 is a cross-sectional view showing a step of attaching the second chiplet 140 on a first carrier 200.

Referring to FIG. 5, the second chiplet 140 may be attached on the first carrier 200. First, the first carrier 200 may be provided. The carrier 210 may be formed of and/or include, for example, a silicon-based material such as glass or silicon oxide, an organic material, or another material such as aluminum oxide, any combination of these materials, and the like. Then, the second chiplet 140 may be attached on the first carrier 200. In an embodiment, the second chiplets 140 may be attached to the first carrier 200 using a laser bonding process. In the second chiplet 140, the upper silicon insulation layer 154 and the upper bonding pads 152 for performing hybrid bonding may be formed on the second active region 141.

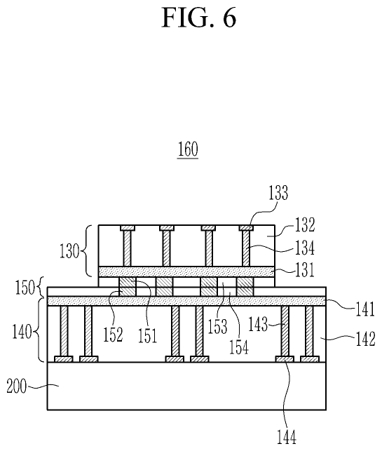

FIG. 6 is a cross-sectional view showing a step of bonding the first chiplet 130 to the second chiplet 140.

Referring to FIG. 6, the first chiplet 130 may be bonded to the second chiplet 140 by hybrid bonding. In the first chiplet 130, the lower silicon insulation layer 153 and the lower bonding pads 151 for performing hybrid bonding may be formed on the first active region 131.

The lower bonding pad 151 on the first chiplet 130 and the upper bonding pad 152 on the second chiplet 140 may be directly bonded by metal-metal hybrid bonding. A metal bond is formed at an interface between the lower bonding pad 151 and the upper bonding pad 152 by metal-metal hybrid bonding. In an embodiment, the lower bonding pad 151 and the upper bonding pad 152 may be formed of and/or include copper. In another embodiment, the lower bonding pad 151 and the upper bonding pad 152 may be a metallic material to which the hybrid bonding is applicable.

The lower bonding pad 151 and the upper bonding pad 152 may be made as a same material, and after the hybrid bonding, the interface between the lower bonding pad 151 and the upper bonding pad 152 may disappear. Through the lower bonding pad 151 and the upper bonding pad 152, the first chiplet 130 may be electrically connected to the second chiplet 140.

The lower silicon insulation layer 153 and the upper silicon insulation layer 154 may be directly bonded by non-metal-non-metal hybrid bonding. A covalent bond is formed at an interface between the lower silicon insulation layer 153 and the upper silicon insulation layer 154 by non-metal-non-metal hybrid bonding.

In an embodiment, the lower silicon insulation layer 153 and the upper silicon insulation layer 154 may be formed of and/or include silicon oxide or TEOS formation oxide. In an embodiment, the lower silicon insulation layer 153 and the upper silicon insulation layer 154 may be formed of and/or include SiO2. In an embodiment, the lower silicon insulation layer 153 and the upper silicon insulation layer 154 may be silicon nitride, silicon oxynitride or other suitable dielectric material. In an embodiment, the lower silicon insulation layer 153 and the upper silicon insulation layer 154 may include SiN or SICN.

The lower silicon insulation layer 153 and the upper silicon insulation layer 154 may be made of the same material, and after the hybrid bonding, the interface between the lower silicon insulation layer 153 and the upper silicon insulation layer 154 may disappear.

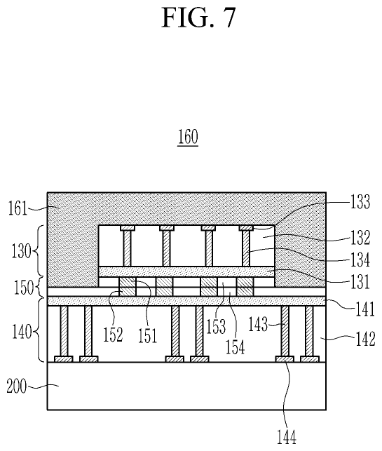

FIG. 7 is a cross-sectional view showing a step of molding the first chiplet 130 with the first molding material 161 on the second chiplet 140.

Referring to FIG. 7, the first chiplet 130 may be molded with the first molding material 161 on the second chiplet 140. In an embodiment, process of molding with the first molding material 161 may include a compression molding or transfer molding process. In an embodiment, the first molding material 161 may include epoxy molding compound (EMC).

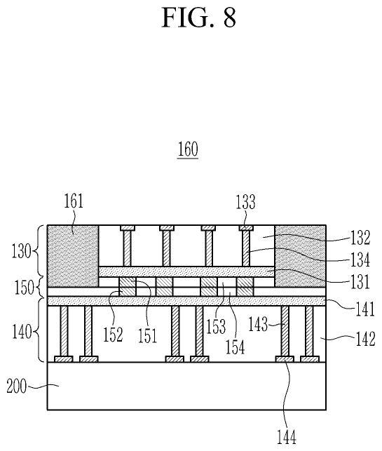

FIG. 8 is a cross-sectional view showing a step of planarizing the first molding material 161.

Referring to FIG. 8, chemical mechanical polishing (CMP) may be performed to level the upper surface of the first molding material 161. The upper surface of the first molding material 161 may be planarized by applying the CMP process. After performing the CMP process, the bottom surface of the first chiplet 130 and the lower connection pads 133 may be exposed from the first molding material 161.

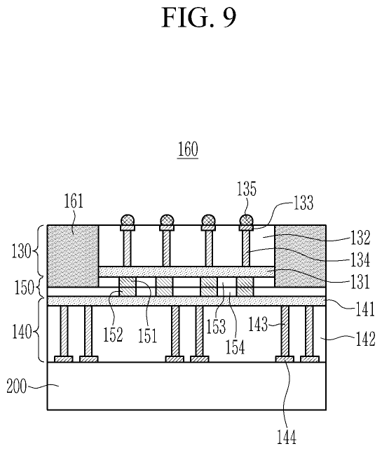

FIG. 9 is a cross-sectional view showing a step of forming the connection members 135 on the lower connection pads 133 of the first chiplet 130.

Referring to FIG. 9, the connection members 135 may be formed on the lower connection pads 133 of the first chiplet 130. In an embodiment, the connection member 135 may be formed of and/or include at least one of tin, silver, lead, nickel, copper, or an alloy thereof.

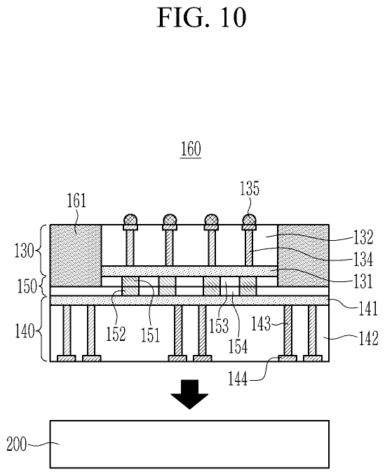

FIG. 10 is a cross-sectional view showing a step of de-bonding the first carrier 200 from the second chiplet 140.

Referring to FIG. 10, the first carrier 200 may be de-bonded from the second chiplet 140.

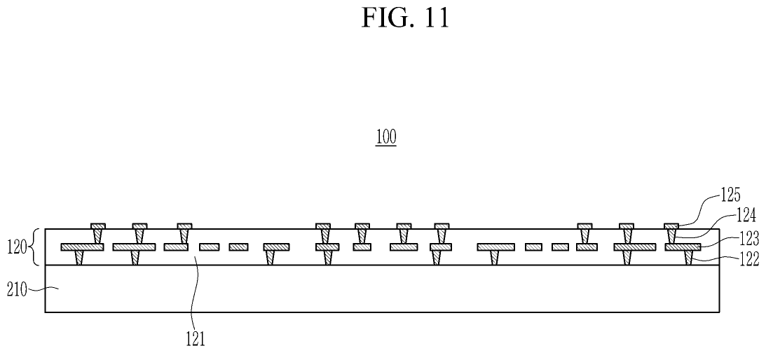

FIG. 11 to FIG. 17 are cross-sectional views showing a method for manufacturing the semiconductor package 100 of an embodiment. FIG. 11 is a cross-sectional view showing a step of forming the redistribution layer structure 120 on a second carrier 210.

Referring to FIG. 11, the redistribution layer structure 120 may be formed on the second carrier 210. First, the second carrier 210 may be provided. In an embodiment, the carrier 210 may include, for example, a silicon-based material such as glass or silicon oxide, an organic material, or another material such as aluminum oxide, any combination of these materials, and the like. Next, the dielectric layer 121 is formed on the second carrier 210. In one embodiment, the dielectric layer 121 may include a photoimageable dielectric (PID) used in a redistribution process. A photoimageable dielectric is a material capable of forming a fine pattern by applying a photolithography process. As an embodiment, photoimageable dielectric (PID) may include polyimide-based photoactive polymer, novolac-based photoactive polymer, polybenzoxazole, silicone-based polymer, acrylate-based polymer, or epoxy-based polymer. In another embodiment, dielectric layer 121 is formed of an inorganic dielectric material such as silicon nitride, silicon oxide, or the like. In an embodiment, the dielectric layer 121 may be formed by a CVD, ALD, or PECVD process.

After forming the dielectric layer 121, via holes may be formed by selectively etching the dielectric layer 121, and the first redistribution vias 122 may be formed by filling the via holes with a conductive material.

Then, the dielectric layer 121 may be additionally deposited on first redistribution vias 122 and the dielectric layer 121, openings may be formed by selectively etching the additionally deposited dielectric layer 121, and the first redistribution lines 123 may be formed by filling the openings with a conductive material.

Then, the dielectric layer 121 may be additionally deposited on first redistribution lines 123 and the dielectric layer 121, via holes may be formed by selectively etching the additionally deposited dielectric layer 121, and the second redistribution vias 124 may be formed by filling the via holes with a conductive material.

Then, a photoresist (not shown) may be additionally deposited on second redistribution vias 124 and the dielectric layer 121, a photoresist pattern including via holes may be formed by selectively exposing and developing the photoresist, and bonding pads 125 may be formed by filling the via holes with a conductive material.

In an embodiment, the first redistribution vias 122, the first redistribution lines 123, the second redistribution vias 124, and the bonding pads 125 may be formed of and/or include at least one of copper, aluminum, tungsten, nickel, gold, tin, titanium, and an alloy thereof. In an embodiment, the first redistribution vias 122, the first redistribution lines 123, the second redistribution vias 124, and the bonding pads 125 may be formed by performing a sputtering process. In another embodiment, the first redistribution vias 122, the first redistribution lines 123, the second redistribution vias 124, and the bonding pads 125 may be formed by performing an electrolytic plating process after forming a seed metal layer.

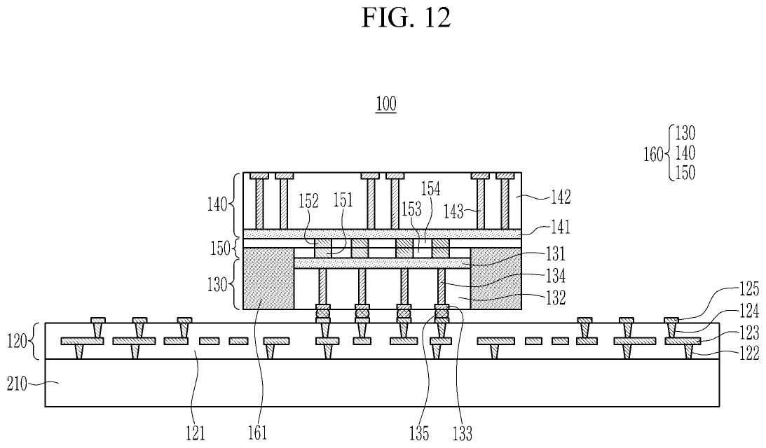

FIG. 12 is a cross-sectional view showing a step of mounting the first semiconductor stack structure 160 on the redistribution layer structure 120.

Referring to FIG. 12, the first semiconductor stack structure 160 may be mounted on the redistribution layer structure 120 by flip chip bonding. The connection member 135 of the first semiconductor stack structure 160 may be bonded to the bonding pad 125 of the redistribution layer structure 120, and thus the first semiconductor stack structure 160 and the redistribution layer structure 120 may be electrically connected.

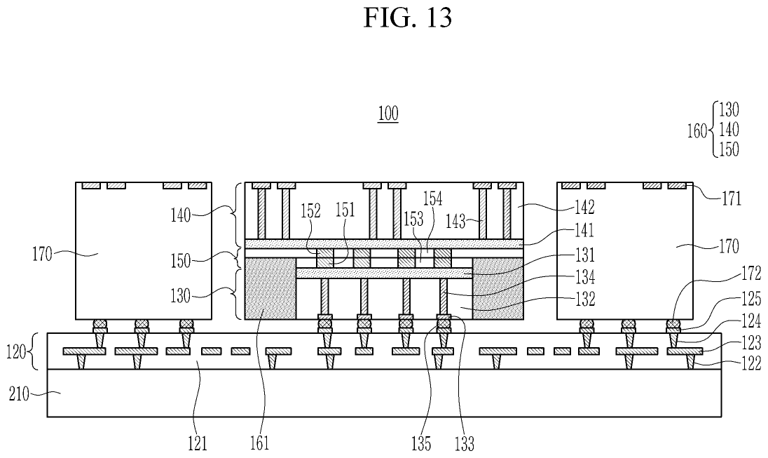

FIG. 13 is a cross-sectional view showing a step of mounting the second semiconductor stack structure 170 on the redistribution layer structure 120.

Referring to FIG. 13, the second semiconductor stack structure 170 may be mounted on the redistribution layer structure 120 by flip chip bonding. The first semiconductor stack structure 160 and the second semiconductor stack structure 170 may be horizontally disposed side by side and at the same level. The connection member 172 of the second semiconductor stack structure 170 may be bonded to the bonding pad 125 of the redistribution layer structure 120, and thus the first semiconductor stack structure 160 and the redistribution layer structure 120 may be electrically connected.

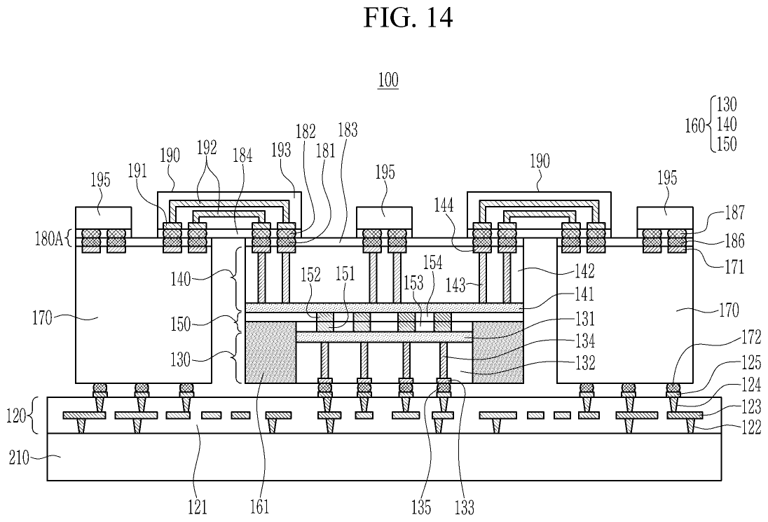

FIG. 14 is a cross-sectional view showing a step of hybrid bonding the bridge die 190 on the upper surface of the first semiconductor stack structure 160 and the upper surface of the second semiconductor stack structure 170, and hybrid bonding the surface mount device (SMD) 195 on at least one of the upper surface of the first semiconductor stack structure 160 and the upper surface of the second semiconductor stack structure 170.

Referring to FIG. 14, the bridge die 190 may be hybrid bonded on a portion of the upper surface of the first semiconductor stack structure 160 and on a portion of the upper surface of the second semiconductor stack structure 170, and the surface mount device (SMD) 195 may be hybrid bonded on at least one of the upper surface of the first semiconductor stack structure 160, and the upper surface of the second semiconductor stack structure 170. The lower silicon insulation layer 183 and the lower bonding pads 181 for performing hybrid bonding may be formed on the upper surface of the first semiconductor stack structure 160 and the upper surface of the second semiconductor stack structure 170, and the upper silicon insulation layer 184 and the upper bonding pads 182 for performing hybrid bonding may be formed on the bottom surface of the bridge die 190 and a bottom surface of the surface mount device (SMD) 195.

The lower bonding pad 181 and the upper bonding pad 182 may be directly bonded by metal-metal hybrid bonding. By the metal-metal hybrid bonding, a metal bond is formed at the interface between the lower bonding pad 181 and the upper bonding pad 182. In an embodiment, the lower bonding pad 181 and the upper bonding pad 182 may be formed of and/or include copper. In another embodiment, the lower bonding pad 181 and the upper bonding pad 182 may be a metallic material to which the hybrid bonding is applicable.

The lower bonding pad 181 and the upper bonding pad 182 may be made as a same material, and after the hybrid bonding, the interface between the lower bonding pad 181 and the upper bonding pad 182 may disappear. Through the lower bonding pad 181 and the upper bonding pad 182, the first semiconductor stack structure 160 or the second semiconductor stack structure 170 may be electrically connected to the bridge die 190 or the surface mount device (SMD) 195.

The lower silicon insulation layer 183 and the upper silicon insulation layer 184 may be directly bonded by non-metal-non-metal hybrid bonding. A covalent bond is formed at an interface between the lower silicon insulation layer 183 and the upper silicon insulation layer 184 by non-metal-non-metal hybrid bonding.

In an embodiment, the lower silicon insulation layer 183 and the upper silicon insulation layer 184 may be formed of and/or include silicon oxide or TEOS formation oxide. In an embodiment, the lower silicon insulation layer 183 and the upper silicon insulation layer 184 may include SiO2. In an embodiment, the lower silicon insulation layer 183 and the upper silicon insulation layer 184 may be silicon nitride, silicon oxynitride or other suitable dielectric material. In an embodiment, the lower silicon insulation layer 183 and the upper silicon insulation layer 184 may include SiN or SiCN.

The lower silicon insulation layer 183 and the upper silicon insulation layer 184 may be made of the same material, and after the hybrid bonding, the interface between the lower silicon insulation layer 183 and the upper silicon insulation layer 184 may disappear.

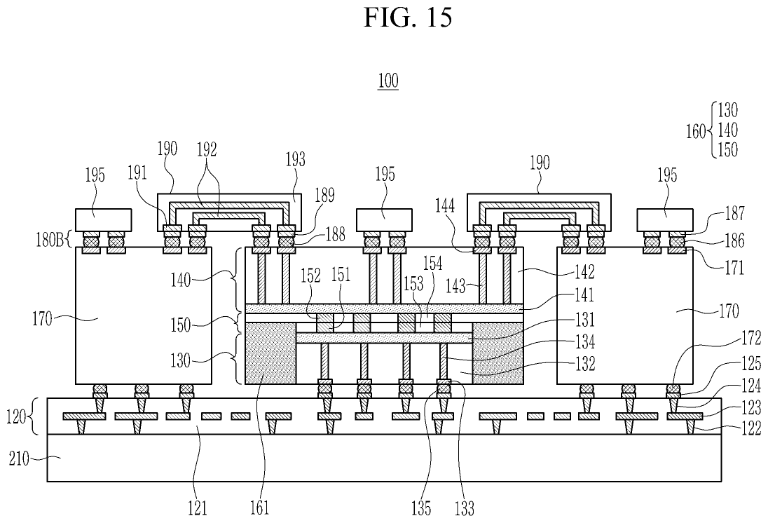

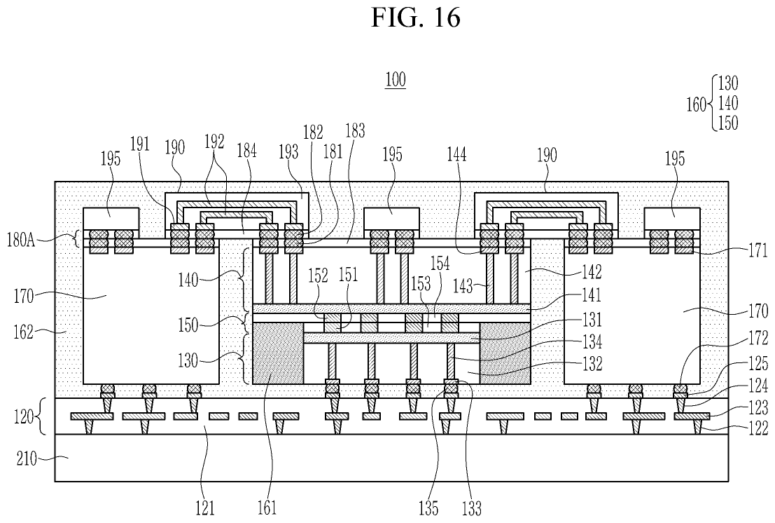

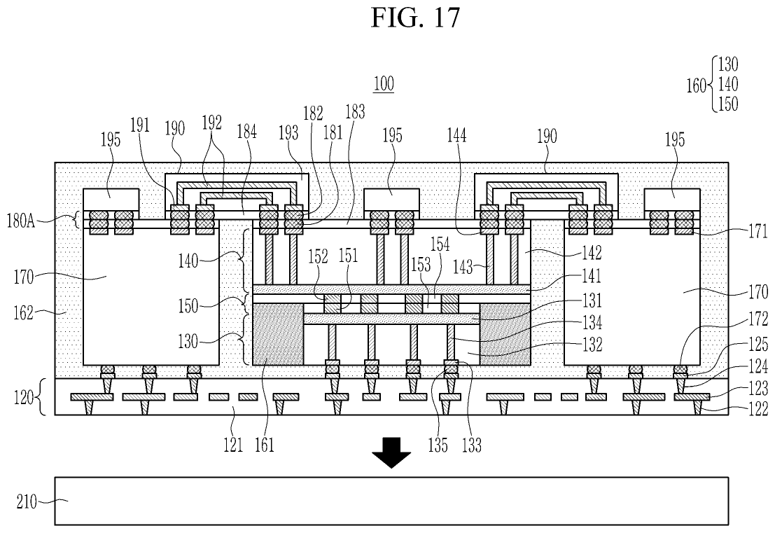

FIG. 15 is, subsequent to FIG. 13, a cross-sectional view showing a step of flip chip bonding the bridge die 190 on the upper surface of the first semiconductor stack structure 160 and the upper surface of the second semiconductor stack structure 170, and flip chip bonding the surface mount device (SMD) 195 on at least one of the upper surface of the first semiconductor stack structure 160, and the upper surface of the second semiconductor stack structure 170. FIG. 15 is a cross-sectional view showing a method for manufacturing the semiconductor package 100 of another embodiment of FIG. 4. A method for manufacturing the semiconductor package 100 of an embodiment of FIG. 1, as shown in FIG. 16 and FIG. 17, may be applied to a method for manufacturing the semiconductor package 100 of another embodiment of FIG. 4.

In FIG. 14, the first semiconductor stack structure 160 and the bridge die 190, the first semiconductor stack structure 160 and the surface mount device (SMD) 195, the second semiconductor stack structure 170 and the bridge die 190, and the second semiconductor stack structure 170 and the surface mount device (SMD) 195 are connected by hybrid bonding, but in comparison, in FIG. 15, the first semiconductor stack structure 160 and the bridge die 190, the first semiconductor stack structure 160 and the surface mount device (SMD) 195, the second semiconductor stack structure 170 and the bridge die 190, and the second semiconductor stack structure 170 and the surface mount device (SMD) 195 may be connected by flip chip bonding. Flip chip bonding may be performed by performing a reflow process.

FIG. 16 is a cross-sectional view showing a step of molding the first semiconductor stack structure 160, the second semiconductor stack structure 170, the bridge die 190, and the surface mount device (SMD) 195 on the redistribution layer structure 120 with the second molding material 162.

Referring to FIG. 16, on the redistribution layer structure 120, the first semiconductor stack structure 160, the second semiconductor stack structure 170, the bridge die 190, and the surface mount device (SMD) 195 may be molded by the second molding material 162. In an embodiment, process of molding with the second molding material 162 may include a compression molding or transfer molding process. In an embodiment, the second molding material 162 may include epoxy molding compound (EMC).

FIG. 17 is a cross-sectional view showing a step of de-bonding the second carrier 210 from the redistribution layer structure 120.

Referring to FIG. 17, the second carrier 210 may be de-bonded from the redistribution layer structure 120.

Thereafter, as shown in FIG. 1, the external connection structure 110 may be formed on the bottom surface of the redistribution layer structure 120. The insulation layer 112 may be formed on the dielectric layer 121 bottom surface of the redistribution layer structure 120, and the conductive pads 111 may be formed under the first redistribution vias 122. In an embodiment, the conductive pad 111 may be formed of and/or include at least one of copper, nickel, zinc, gold, silver, platinum, palladium, chromium, titanium, and an alloy thereof. In an embodiment, the insulation layer 112 may be formed of and/or include solder resist. In an embodiment, the external connection member 113 may be formed of and/or include at least one of tin, silver, lead, nickel, copper, or an alloy thereof. In an embodiment, the conductive pad 111 may be formed by performing a sputtering process or an electrolytic plating process after forming a seed metal layer. In an embodiment, the insulation layer 112 may be formed by a CVD, ALD, or PECVD process.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package, comprising:
a redistribution layer structure;
a first semiconductor stack structure on an upper surface of the redistribution layer structure, wherein the first semiconductor stack structure comprises a first chiplet and a second chiplet disposed on the first chiplet;
a second semiconductor stack structure on an upper surface of the redistribution layer structure and side by side with the first semiconductor stack structure;
a bridge die forming an electrical connection between the first semiconductor stack structure and the second semiconductor stack structure, the bridge die being disposed above the first semiconductor stack structure and the second semiconductor stack structure; and
a surface mount device (SMD) on an upper surface of at least one of the first semiconductor stack structure and the second semiconductor stack structure.

2. The semiconductor package of claim 1, wherein the first semiconductor stack structure and a second semiconductor stack structure exchange signals through the bridge die.

3. The semiconductor package of claim 1, wherein:
the first chiplet comprises a first active region positioned at a surface facing the second chiplet.

4. The semiconductor package of claim 3, wherein the first chiplet comprises a plurality of first through-silicon vias extending in a downward direction from a first active region to a back side of the first chiplet.

5. The semiconductor package of claim 1, wherein the second chiplet comprises a second active region positioned at surface facing the first chiplet.

6. The semiconductor package of claim 5, wherein the second chiplet comprises a plurality of second through-silicon vias extending in an upward direction from a second active region to a back side of the second chiplet.

7. The semiconductor package of claim 6, wherein each of the plurality of second through-silicon vias is electrically connected to one of the bridge die or the surface mount device.

8. The semiconductor package of claim 1, wherein the first chiplet
has a first footprint and the second chiplet has a second footprint, and the first footprint is within the second footprint.

9. A semiconductor package, comprising,
a redistribution layer structure;
a first semiconductor stack structure on the redistribution layer structure, wherein the first semiconductor stack structure comprises,
a first chiplet,
a first molding material molding a side surface of the first chiplet,
a second chiplet on the first chiplet and on the first molding material such that the first chiplet is disposed between the redistribution layer structure and the second chiplet, and
a first interconnection structure between the first chiplet and the second chiplet;
a second semiconductor stack structure disposed on the redistribution layer structure and side by side with the first semiconductor stack structure;
a bridge die configured to electrically connect the first semiconductor stack structure and the second semiconductor stack structure, the bridge die being disposed above the first semiconductor stack structure and the second semiconductor stack structure;
a surface mount device (SMD) disposed above at least one of the first semiconductor stack structure and the second semiconductor stack structure; and
a second molding material covering the first semiconductor stack structure, the second semiconductor stack structure, the bridge die, and the surface mount device, on the redistribution layer structure.

10. The semiconductor package of claim 9, wherein the first chiplet comprises a central processing unit (CPU) or a graphic processing unit (GPU).

11. The semiconductor package of claim 9, wherein the second chiplet comprise an SRAM.

12. The semiconductor package of claim 9, wherein the second semiconductor stack structure comprises a high-bandwidth memory (HBM).

13. The semiconductor package of claim 9, wherein the surface mount device comprises a capacitor structure.

14. The semiconductor package of claim 9, further comprising a second interconnection structure between the first semiconductor stack structure, the second semiconductor stack structure, and the bridge die.

15. The semiconductor package of claim 14, wherein the second interconnection structure comprises a micro-bump.

16. The semiconductor package of claim 14, wherein the second interconnection structure comprises:
a first silicon insulation layer and a plurality of first bonding pads on an upper surface of the second chiplet and on an upper surface of the second semiconductor stack structure; and
a second silicon insulation layer and a plurality of second bonding pads on a bottom surface of the bridge die.

17. The semiconductor package of claim 16, wherein each first bonding pad of the plurality of first bonding pads is directly bonded to each second bonding pad of the plurality of second bonding pads.

18. The semiconductor package of claim 16, wherein the first silicon insulation layer is directly bonded to the second silicon insulation layer.

19. A method for manufacturing a semiconductor package, the method comprising:
mounting a first semiconductor stack structure on a redistribution layer structure, wherein the first semiconductor stack structure comprises a first chiplet and a second chiplet on the first chiplet;
mounting a second semiconductor stack structure, on the redistribution layer structure side by side with the first semiconductor stack structure;
mounting a bridge die on the first semiconductor stack structure and on the second semiconductor stack structure, wherein the bridge die is positioned above the first semiconductor stack and the second semiconductor stack structure and electrically connects the first semiconductor stack structure and the second semiconductor stack structure; and
mounting a surface mount device (SMD) on at least one of the first semiconductor stack structure and the second semiconductor stack structure.

20. The method of claim 19, wherein:
the bridge die is mounted on the first semiconductor stack structure and on the second semiconductor stack structure by hybrid bonding.
